(19) United States
(12) Patent Application Publication
(10) Pub. No.: US 2012/0077527 A1
(43) Pub. Date: Mar. 29, 2012

(54) NETWORK EVENT IDENTIFICATION AND METHOD OF OPERATION

(75) Inventors: David Santiago, Haverstraw, NY (US); George Baroudi, New York, NY (US); Cristiana Dimitriu, Teaneck, NJ (US); Peter Hofmann, Hasbrouck Heights, NJ (US)

(73) Assignee: CONSOLIDATED EDISON COMPANY OF NEW YORK, INC., New York, NY (US)

(21) Appl. No.: 12/892,194

(22) Filed: Sep. 28, 2010

(51) Int. Cl. H04W 4/00; G01R 31/02; G06F 19/00; G01R 21/00

(52) U.S. Cl. 455/466; 702/60; 702/58

(57) ABSTRACT

A method and apparatus for detecting events in an electrical network is provided. The method and apparatus measure a plurality of electrical parameters on the electrical network. A precursor event is detected. The measured parameters are captured and analyzed. The precursor event is categorized and a plurality of notifications having integrated data related to the event are electronically transmitted.

### BACKGROUND OF THE INVENTION

The subject matter disclosed herein relates to a system for detecting faults in distribution electrical networks, and in particular to a system that can identify, categorize and notify control center operators of these detected events.

Electrical networks are used in the transmission and distribution of electrical power from generation locations, such as power plants for example, to consumers. The electrical network is a complex, interconnected network involving many miles of cabling and thousands of individual pieces of equipment. Despite this complexity, these electrical networks deliver electrical power at a high level of reliability.

The equipment used in the delivery of electrical power may not operate as desired for a number of reasons. One common issue is the deterioration of electrical insulation due to the stresses of operation, weather factors and time. When the cable or conductor insulation deteriorates in a high voltage circuit, such as distribution feeder operating at 13 kV to 35 kV for example, high levels of energy may be released causing an interruption in service. While these types of events are infrequent, the deterioration of insulation may result in an event that shuts down or disables an individual circuit within the electrical network. It is difficult to predict how or when these random events may impact the reliability of the electrical network.

Currently, distribution control center operators use a combination of visual inspection by field personnel and real-time monitoring to detect a potential event. The operator typically has many monitoring devices that measure desired parameters at discrete locations, such as a substation for example. When a control center operator observes an undesired parameter or a fault event, field personnel are dispatched to locate and identify the anomaly. While this arrangement is typically successful in quickly resolving any issues, in geographically large or congested urban areas, identifying and locating the fault is time and labor intensive. Further complicating the issue is that the data is often silo'ed or segregated in different locations making it difficult for operators to identify conditions that may indicate a potential for events that effect network operation. In areas involving underground distribution feeders, the issues involved with locating the fault may be even more challenging.

While existing network supervisory control and data acquisition (SCADA) systems are suitable for their intended purposes, there remains a need for improvements in the prediction and prevention of distribution feeder failures. In particular there is a need for improvement in the integration of information and providing notification to desired personnel in a timely manner.

### BRIEF DESCRIPTION OF THE INVENTION

According to one aspect of the invention, a computer implemented method of detecting events in an electrical network is provided. The method includes measuring a plurality of electrical parameters on the electrical network. A precursor event is detected. The measured plurality of electrical parameters are captured. The plurality of electrical parameters are analyzed. The precursor event is automatically categorized. A plurality of electronic notifications are transmitted in response to the categorization of the precursor event.

According to another aspect of the invention, an apparatus for detecting events in an electrical network is provided. The apparatus includes a memory and one or more servers in communication with the memory. The one or more servers configured to perform a method that includes measuring a plurality of electrical parameters on the electrical network. A precursor event is detected. The measured plurality of electrical parameters are captured to the memory. The plurality of electrical parameters are analyzed. The precursor event is automatically categorized with the one or more servers. A plurality of electronic notifications are transmitted with the one or more servers in response to the categorization of the precursor event.

According to yet another aspect of the invention, A computer program product for executing a task of detecting events in an electrical network with a computer system, the computer program product comprising: a tangible storage medium readable by a processing circuit and storing instructions for execution by the processing circuit for performing a method comprising: measuring a plurality of electrical parameters on the electrical network; detecting a precursor event; capturing the measured plurality of electrical parameters; analyzing the plurality of electrical parameters; automatically categorizing the precursor event; and, transmitting a plurality of electronic notifications in response to the categorization of said precursor event.

These and other advantages and features will become more apparent from the following description taken in conjunction with the drawings.

### BRIEF DESCRIPTION OF THE DRAWING

The subject matter, which is regarded as the invention, is particularly pointed out and distinctly claimed in the claims at the conclusion of the specification. The foregoing and other features, and advantages of the invention are apparent from the following detailed description taken in conjunction with the accompanying drawings in which:

FIG. 1 is a block diagram of an electrical network fault identification system in accordance with an embodiment of the invention;

FIG. 2 is a block diagram of a typical distribution substation comprising of primary distribution feeders, forming a distribution network in accordance with an embodiment of the invention;

FIG. 3 is a flow diagram for a fault identification and notification system for the system of FIG. 1;

FIG. 4 is an illustration of an email notification in accordance with an embodiment of the invention;

FIG. 5 is an illustration of a reactance to fault website application used to display categorized events in accordance with an embodiment of the invention;

FIG. 6 is an illustration of a oscillography window for use with the notification window of FIG. 5;

FIG. 7 is an illustration of a relay targets window for use with the notification window of FIG. 5;

FIG. 8 is an illustration of an event window on the reactance to fault website to display feeder failure events FIG. 5;

FIG. 9 is an illustration of a heads-up-display window in accordance with an embodiment of the invention;

FIG. 10 is an illustration of a heads-up-display window of FIG. 9 displaying a single feeder view;

FIG. 11 is a flow diagram of the current inrush “magnetizing current” identification and notification system for the system of FIG. 1.

The detailed description explains embodiments of the invention, together with advantages and features, by way of example with reference to the drawings.

### DETAILED DESCRIPTION OF THE INVENTION

Embodiments of the present invention provide a system for identifying and notifying control center operators of faults on the distribution system. In one embodiment, the system simultaneously performs a plurality analysis to identify and categorize the type of fault from measured data. In another embodiment, the system provides simultaneous notifications to control center operators using a plurality of communications mediums. In another embodiment, the system provides a display having information integrated from a plurality of sources. This system provides advantages assisting an operator in predicting an incipient, “self clearing fault”, dispatching service personnel and improving the reliability and operation of an electrical network.

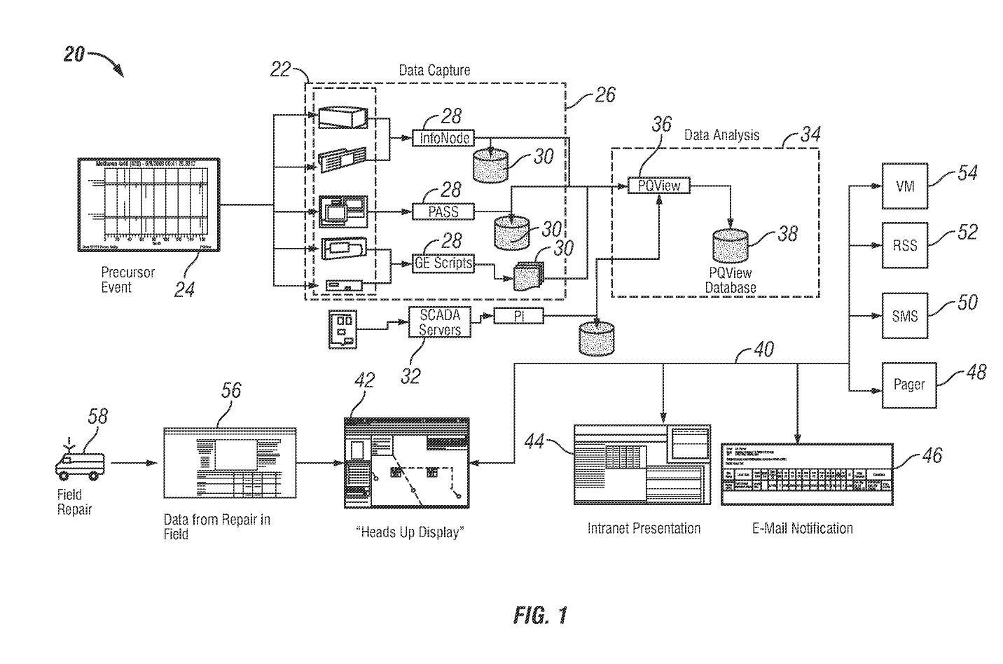

An exemplary embodiment of a system 20 for identifying faults and notifying electrical network operators is illustrated in FIG. 1. The system 20 includes a plurality of devices 22 that are coupled to an electrical distribution or electrical transmission network to monitor the operation of the electrical network. An electrical network is a system that delivers electrical power from a producing location, such as a power plant, a wind turbine or a solar panel for example to a consuming location, such as a residence, commercial building or industrial facility for example. An electrical network is typically divided into an electrical transmission network that delivers high voltage (e.g. greater than 110 kV) electrical power over long distances from the power generation location. An electrical distribution network connects to the electrical transmission network at a substation that reduces high voltage to a medium voltage (e.g. 13 kV to 35 kV). The distribution network transfers the electrical power to the end consumers. Typically, the distribution network includes additional transformers that further reduce the electrical voltage to lower voltages (e.g. 110V, 277V) used by the end consumers.

As used herein, the term electrical network may refer to a distribution network, a transmission network or the combination of a distribution and transmission network. Embodiments described herein may refer to a distribution network, the claimed invention should not be so limited and the claimed invention may be used with either a distribution network, a transmission network or a combination of a distribution and transmission network. Further, the electrical network may be operated by a government entity, a private entity, or a regulated company (sometimes referred to as a public utility) or a combination thereof.

The devices 22 are coupled to the electrical network to monitor desired parameters such as faults or precursor events 24 may be measured. A data capture module 26 acquires the measured data. The data capture module 26 may include the devices 22, intermediary or conversion modules 28 and databases 30. The intermediary modules 28 convert or transform the measured electrical (e.g. voltage or current) or physical (e.g. temperature) data into a form that is usable for further analysis. In one embodiment, one of the intermediary modules 28 is an InfoNode manufactured by Dranetz-BMI Company. In the exemplary embodiment, each of the intermediary modules 28 includes an associated database 30 to store measured data.

The information from the data capture module 26 is combined with information from supervisory control and data acquisition (SCADA) servers 32 in a data analysis module 34. The data captured at the distribution substation and stored in the server includes but is not limited to station real power and imaginary power (MW, MVars), bus voltage (V), transformer current (Amps), transformer tap positions, feeder current (Amps), and network load (MW). It should be appreciated that databases 30 may continuously transmit information to the data analysis module 34, or may transmit such information in a batch process. In one embodiment, the information is transmitted directly from the intermediary modules 28 to the data analysis module 34.

Data analysis module 34 may include one or more systems that are capable of analyzing and determining electrical characteristics from a large volume of continuous data. In one embodiment, the data analysis module 34 may include a server 36, such as model PQView manufactured by Electrotek Concepts, Inc. for example. The server 36 receives data from the data capture module 26 and builds databases 38 with measurements from a plurality of monitoring points taken by many different types of sensors, including utility meters, power quality monitors, voltage recorders, microprocessor protective relays, circuit breakers, phase measurement units (PMU's) and digital fault recorders for example. As will be discussed in more detail below, the data analysis module may store and analyze information with the measurements about cause and source of undesired events.

The server 36 may be implemented using one or more servers operating in response to a computer program stored in a storage medium accessible by the server 36. The server 36 may operate as a network server (e.g., a web server) to communicate with the data capture module 26. The server 36 handles sending and receiving information from the data capture module 26 and can perform associated tasks. The server 36 may also include firewalls to prevent unauthorized access and enforce any limitations on authorized access. A firewall may be implemented using conventional hardware and/or software as is known in the art.

The data analysis module 34 is coupled to a data communications medium 40. The communications medium 40 may be any type of known communications system or network including, but not limited to, a wide area network (WAN), a public switched telephone network (PSTN) a local area network (LAN), a global network (e.g. Internet), a virtual private network (VPN), and an intranet. The communications medium 40 may be implemented using a wireless network or any kind of physical network implementation known in the art.

As will be discussed in more detail below, the data analysis module 34 communicates with control center operators and receives instructions via the communications medium 40. In one embodiment, the data analysis module 34 transmits integrated information and data, such as event categorization for example, over the communications medium 40 using a plurality of different protocols to allow the information and data to be accessed by a plurality of devices. These devices and protocols include but are not limited to computer displays (“Heads Up Display”) 42 in the control center, web pages 44 displayed on a network engineer or field personnel computer, an email 46, a pager 48, a short message service (SMS) message 50, a really-simple-syndication (RSS) feed 52, or a voicemail 54 for example.

In one embodiment, the devices may also receive additional information and data from other devices or servers coupled to the communications medium 40, such as data may include field service databases 56 that are updated in real or near-real time by field personnel 58 that are performing repairs.

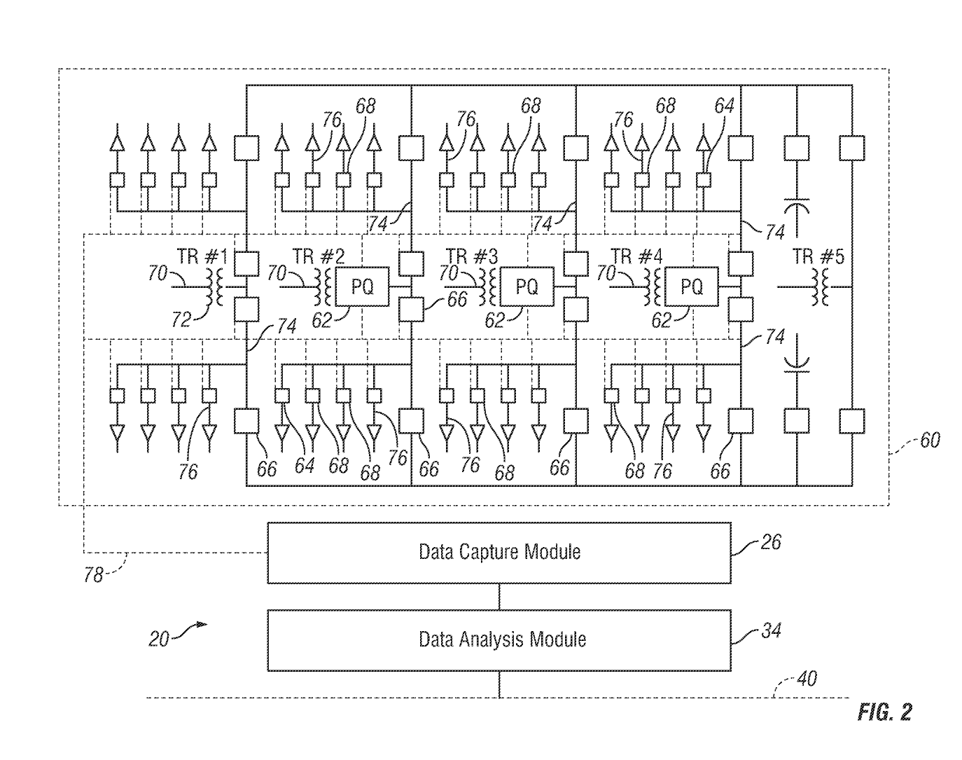

One embodiment of the system 20 is illustrated in FIG. 2. In this embodiment, a substation 60 is provided with a plurality of sensors. These sensors may include, but are not limited to, power quality meters 62, microprocessor relays 64, and revenue meters 68 for example. The sensors may be coupled to any desired portion of the substation 60, including transmission lines 70, transformers 72, bus circuits 74, or distribution feeder circuits 76 for example. The sensors are also coupled to a second communications medium 78 that connects each of the individual sensors to the data capture module 26. The second communications medium 78 allows the sensors to communicate with data capture module 26 using a well-known computer communications protocol such as TCP/IP (Transmission Control Protocol/Internet) Protocol), RS-232, ModBus, and the like. Additional systems 20 or substations 60 may also be connected to the second communications medium 78 or be configured to send and receive data to and from remote computers (not shown). The second communications medium 78 may also be connected to the Internet or an intranet.

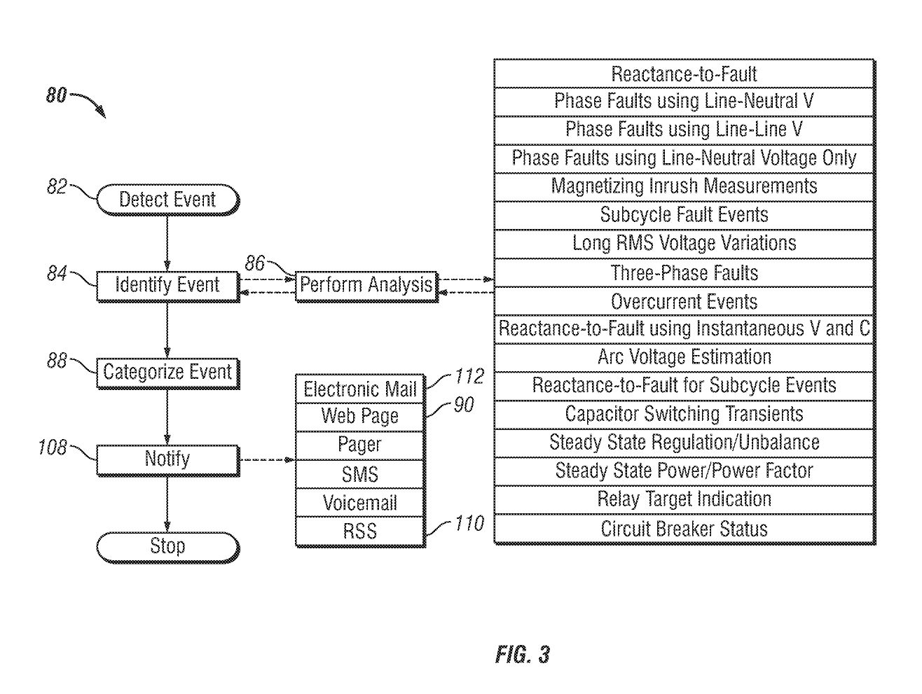

The system 20 may also be illustrated in terms of a method operation as shown in FIG. 3. In this embodiment, the method 80 initiates when an undesired operating condition, such as precursor event or a fault for example, is detected in block 82. A precursor event is an undesired operating condition that while not materially effecting the operation of the network may indicate a potential for a fault to occur. For example, a subcycle event may be caused by a variety of factors. While the detection of a single subcycle event may not be of concern, if a number of subcycle (incipient fault) events are detected within a defined period of time, this may indicate a near future feeder failure based on historic events analyzed.

The process 80 proceeds to block 84 where the event is identified. In the exemplary embodiment, the method 80 performs desired analysis related to electrical characteristics and known fault event conditions in block 86. These analysis may be performed simultaneously, in parallel or in series. The analysis include, but are not limited to estimates of Reactance-to-Fault using phasors; single-phase and multi-phase faults using Line-Neutral Voltage and Line Current measurements; single-phase and multi-phase faults using Line-Line Voltage and Line Current measurements; single-phase faults using Line-Neutral Voltage only; magnetizing inrush measurements; subcycle fault events; long RMS Voltage variations; three-phase faults; overcurrent events; estimates of Reactance-to-Fault using instantaneous Voltage and Current samples; arc Voltage estimation; Reactance-to-Fault for subcycle events; capacitor switching transients; steady state regulation/unbalance; steady state power/power factor; microprocessor protective relay target indications; recloser status and, circuit breaker status for example. It should be appreciated that the method 80 may perform one or more of the analysis to assist in the identification of the event.

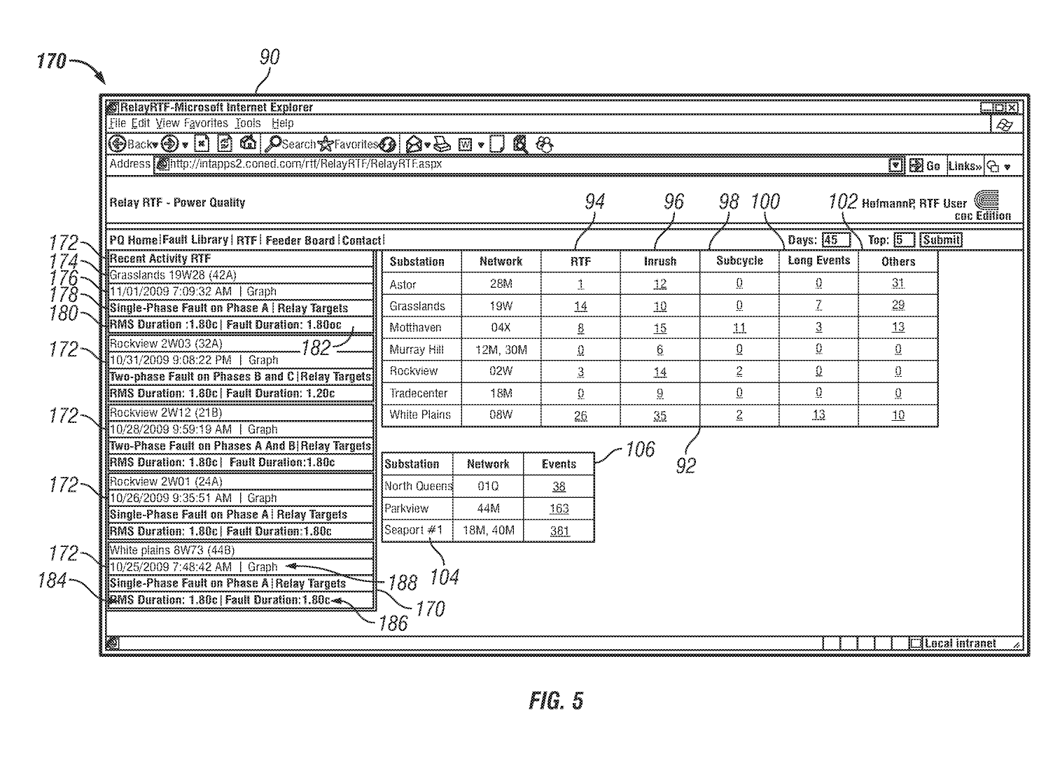

Once the analysis is performed, the method 80 proceeds to block 88 where the event is categorized. The event may be categorized as a precursor event that does not effect operation, or as a fault that affects operation. In the exemplary embodiment, the categorization occurs automatically without intervention by a control center operator or engineer. The categorization of the event may also be an identification of an analysis that indicates a parameter outside the desired range, or the categorization block 88 may group certain types of event together, while specifically identifying other desired event types. As will be discussed in more detail below, in one embodiment, the system 20 updates a web page 90 (FIG. 5) having a sub-window 92 that displays each of the substations 60 available on the distribution system and categorizes the type of events triggered, detected by the monitors 22 at those substations 60 during a particular period. In this embodiment, the sub-window 92 includes user definable event types, such as reactance-to-fault 94, magnetizing inrush 96, subcycle faults 98, long events 100 and all others 102. The web page 90 may also include a second sub-window 104 for a second set of substations 60 which only track the total number of events 106 for example. The types of protocols 110 may include, but are not limited to electronic mail, web pages, pager messages, short messaging service (SMS), multimedia messaging service (MMS), voicemail messages, and really-simple-syndication feeds (RSS).

Once the event has been categorized in block 88, the method 80 proceeds to block 108 where notifications are transmitted. In the exemplary embodiment, the method 80 transmits notification using a plurality of protocols 110 so that the control center operators, engineers, service personnel and others may receive communications regarding the event. In one embodiment, the plurality of protocols 110 are transmitted simultaneously to designated personnel. In another embodiment, the personnel may pre-select the type of notification they desire to receive. In yet another embodiment, the type of notification that a particular person may receive may depend on the type of event that has been categorized.

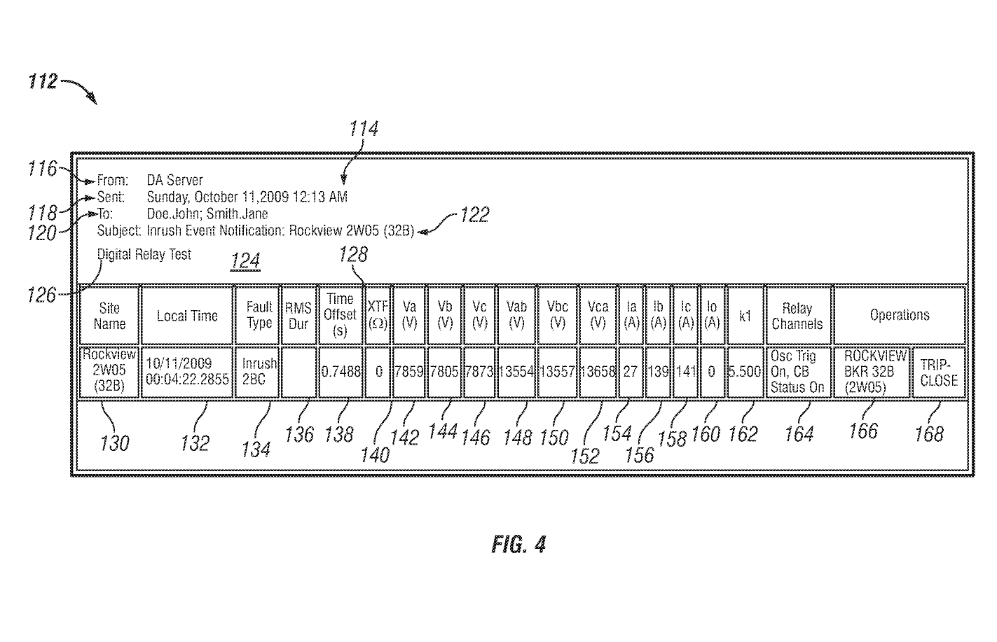

An exemplary embodiment of an electronic mail (e-mail) notification 112 is illustrated in FIG. 4. The email notification 112 includes a header portion 114 that includes sender information 116, transmittal date information 118, recipient information 120, and subject information 122. The e-mail notification 112 also includes a body portion 124, and monitor type description 126 and a data table 128. The data table 128 provides a display of parameters from different sources that are integrated into a single view for the recipient. In one embodiment, these parameters are associated with the event and the type fault that was categorized. In the exemplary embodiment, the data portion 128 includes a site name 130 where the event occurred or was detected, the time of the event 132, the event type 134. The data portion 128 may also include a variety of electrical parameters that may be appropriate for the type of event, including RMS Duration 136, Time Offset 138, Reactance to fault (XTF) calculated value 140, Phase-Neutral Voltages 142, 144, 146, Phase-Phase Voltages, 148, 150, 152, Phase Currents 154, 156, 158, neutral current 160 and k1 factor 162. The k1 factor is a factor used to adjust for zero sequence impedance in the feeder model. The k1 factor is empirically determined from first few feeder faults in a network. The data portion 128 may further include information on the state, status or actions of equipment in reaction to the event. This equipment information may include relay channel information 164, a circuit breaker identity 166 and circuit breaker operation 168.

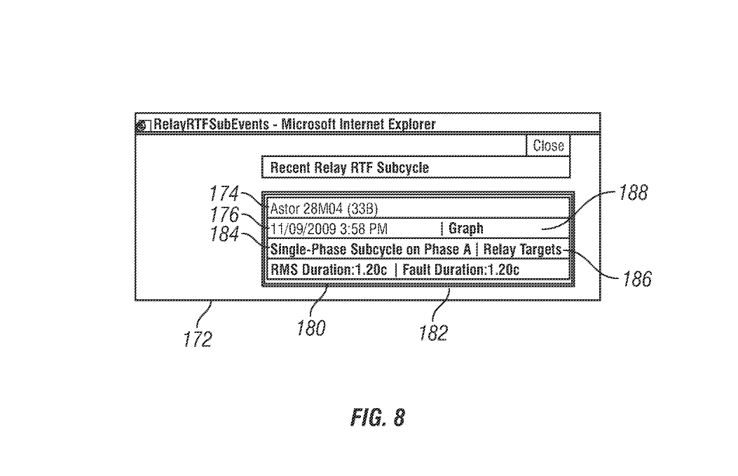

An exemplary embodiment of a web page notification 90 is illustrated in FIG. 5. As discussed above, the web page notification 90 includes a plurality of sub-windows including first substation summary sub-window 92, second substation summary sub-window 104, and an event activity sub-window 170. In one embodiment, the web page notification 90 provides a plurality of summaries for multiple events. For example, the event activity sub-window 170 includes a summary of the five most recent (in time) events. In one embodiment, the user may define the number of events that are displayed in the event activity sub-window 170. The sub-window 170, is further sub-divided into portions 172 that provide a summary of each discrete event. As illustrated in FIG. 5 and FIG. 8, each event 172 includes a name portion 174 that provides the name of the substation where the event occurred or was detected, a date portion 176 for the date and time of the event, a plurality of hyperlinks 178, and two data fields describing the RMS duration 180 and the fault duration 182.

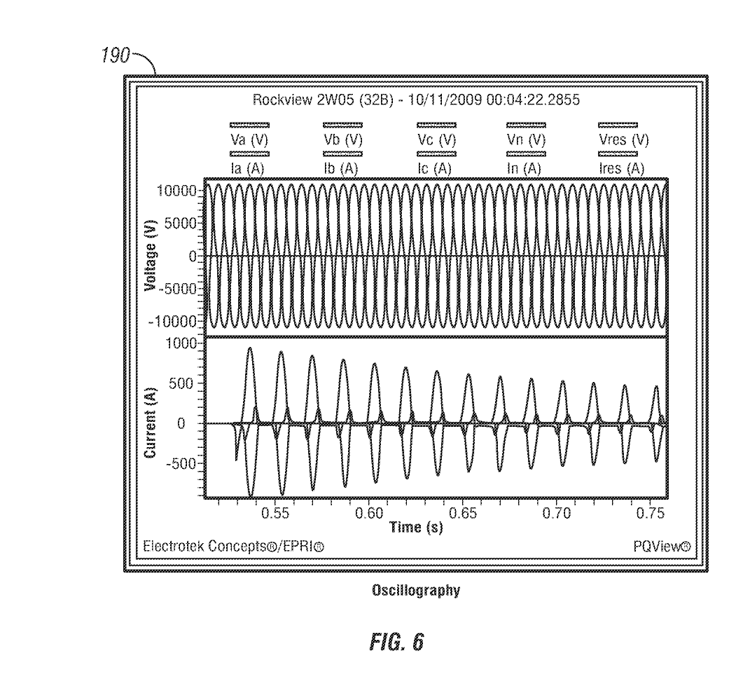

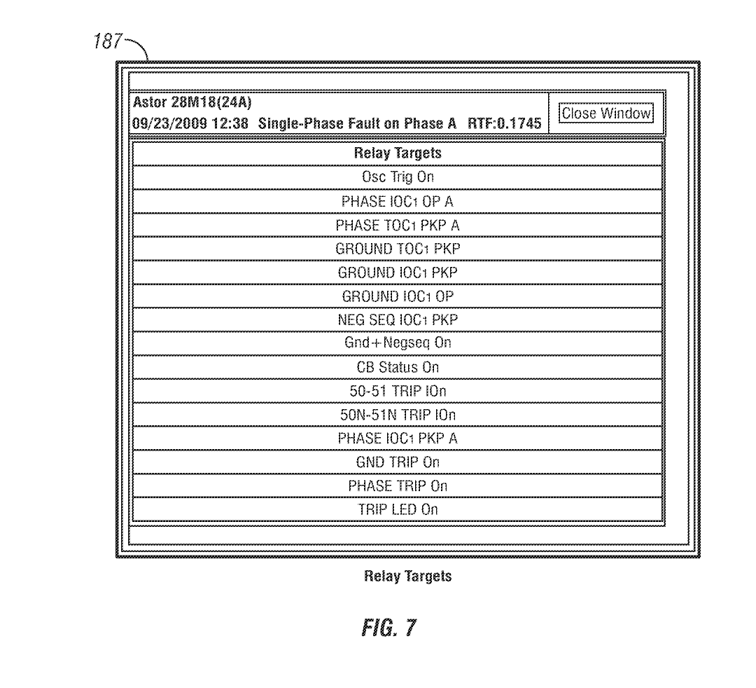

In one embodiment, one of the hyperlinks 178 includes a hyperlink 184 that describes the type of event, a hyperlink 186 the displays relay target information such as window 187 illustrated in FIG. 7 for example. The window 187 displays an indication for the status for each of the protective relay indicators or flags at the substation associated with the event. The hyperlinks 178 may also include a hyperlink 188 that displays a graphical representation of the measurements recorded during the event. By clicking on the hyperlink 188, the operator accesses additional and more detailed information and measurements on the event such as a window 190 illustrated in FIG. 6 that displays an oscillograph of current and voltage for the event.

The first substation summary sub-window 92 provides the operator with a graphical display of the number of types of categorized events that have occurred at a particular substation. This provides advantages in allowing operators to see if there are repetitive events that occurs during periods of time. This allows the operator to focus on areas where there may be an addressable issue rather than pursuing single random events. For example, a sub-cycle fault may occur for a variety of reasons that do not materially effect the operation or reliability of the electrical network. However, when a series of these faults occur at the same location over a period of time, such a month for example, then the operators may need to conduct further investigations to determine the source of the arcing along the feeder. Using the arc voltage reactance method, the operator is able to identify the structure that arced, inspect the equipment, remove the feeder out of service if needed, and replace any damage equipment.

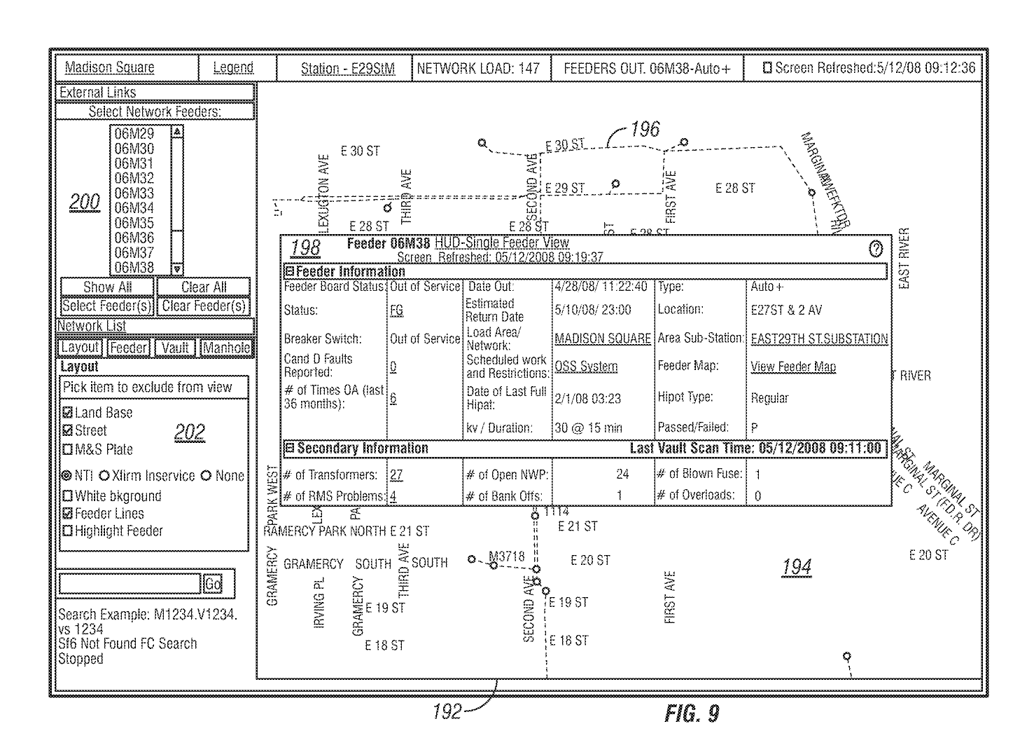

An exemplary embodiment for a heads-up display 192 that may also be used for providing a notification of an event as illustrated in FIG. 9. In one embodiment, a heads-up display 192 is one of the displays available in the control center, where real-time or near real-time data on the operation of the distribution network is displayed. In this embodiment, the heads-up display 192 includes a map portion 194 that provides a graphical representation of the network, such as an electrical network, a gas network or a water-supply network for example. The map portion 194 may include graphical representations 196 that indicate the status or parameters of components, such as current, voltage, or temperature for example. In one embodiment, the notification on heads-up display 192 may be a window 198 that shows integrated data and information about a particular portion or section of the network being monitored. The heads-up display 192 may also include a sub-window 200 that allows the operator to select which portions (e.g. feeder circuits) of the network to display. The heads-up display 192 may further include a sub-window 202 that allows the operator to select items to exclude from the display.

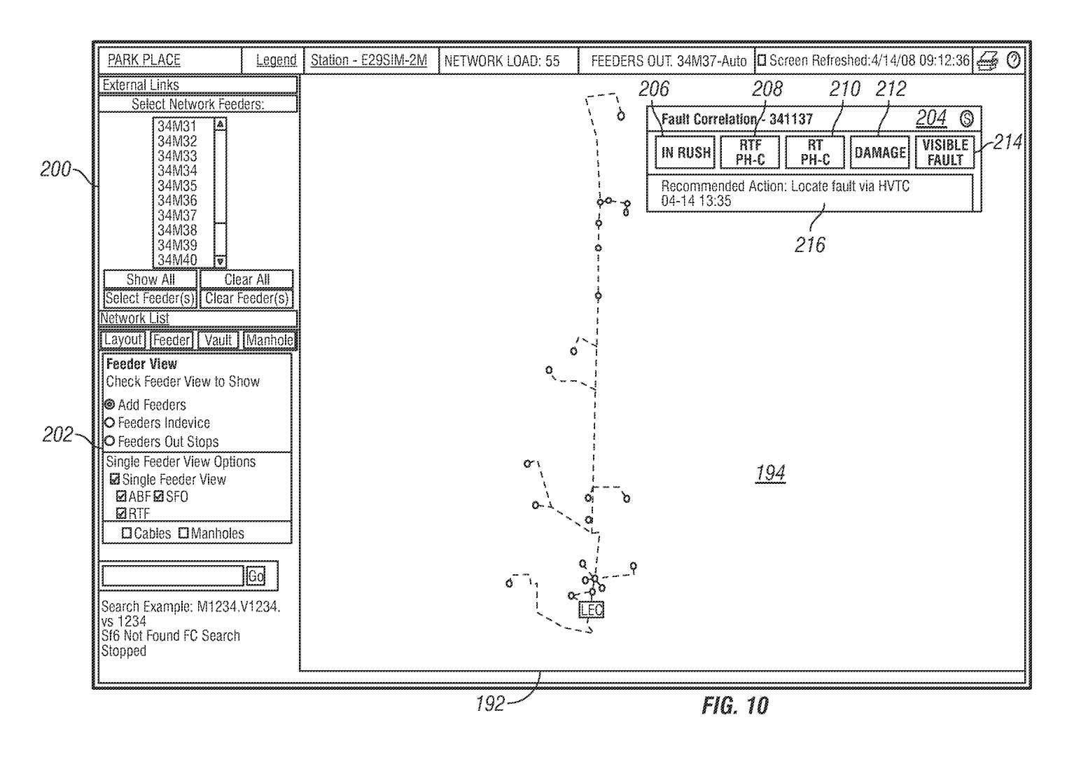

Another embodiment of heads-up display 192 is illustrated in FIG. 10. In this embodiment, the heads-up display 192 includes a window 204 that provides notification of an event. This window 204 includes a plurality of portions to display integrated information that may be desired by the operator in making decisions in response to the event. In one embodiment, the window 204 includes a event type portion 206, a reactance to fault calculation 208, a relay target “RT” indication portion 210. A damage indicator box 212 turns on when a manhole smoke or fire observed by the general public or coned personnel in the field is reported back to the control center, before the structure is inspected for feeder fault. A visible fault indicator box 214 turns on when the field crews, identify and verify the fault inside the structure. The window 204 may also include a action portion 216 that provides the operators with a recommendation on how to react or what procedures should be executed in response to the event category.

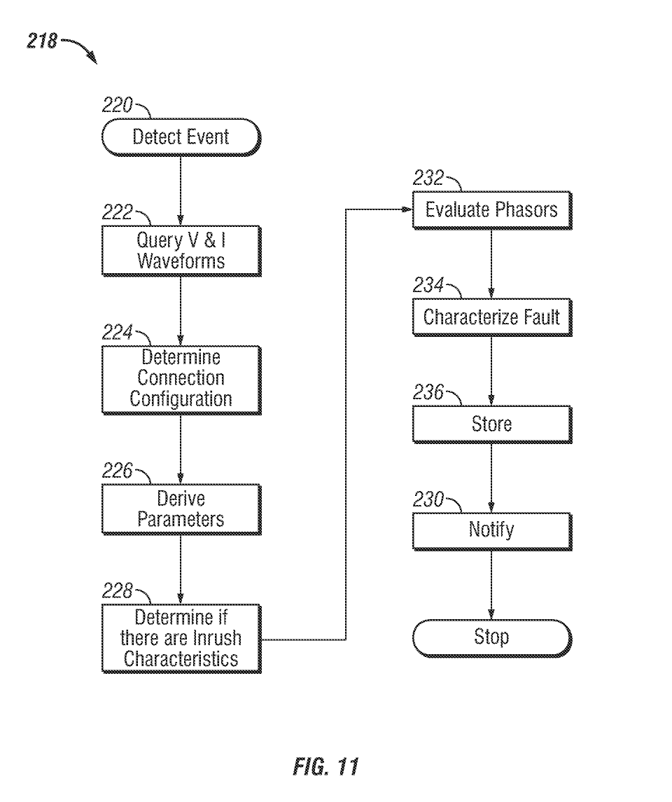

The system 20 may also be illustrated in terms of a method operation as shown in FIG. 11. In this embodiment, a method 218 initiates when an undesired event, such as precursor event or a fault is detected in block 220. The method 218 then proceeds to block 222 where the voltage and current waveforms are queried. In block 224, the connection configuration is determined for phase type single line to ground/multi-phase line to line/and or transformer delta-Wye connection. The method 218 then proceeds to block 226 where desired parameters are derived such as reactance, impedance, event duration, phase angle for example. With the calculated parameters determined, the method 218 proceeds to block 228 where it is determined if there are in-rush characteristics to the event. In one embodiment, if in-rush characteristics are present, then the method 218 flags the event as an in-rush and proceeds to transmit the notifications in block 230. Otherwise, the method 218 proceeds to block 232 where the phasors are evaluated. The results of this evaluation are used in characterizing the fault in block 234. The method 218 stores the information in block 236 and transmits notifications in block 230. In one embodiment, the transmission of notifications is substantially similar to that described herein with respect to FIG. 3.

Technical effects and benefits of embodiments include the display and notification of network operators of integrated information for assisting the prediction of incipient faults within an electrical network. This provides advantages in predicting or anticipating the locations of events, which allows network operators to initiate corrective actions. As a result, the reliability of the electrical network is increased while decreasing repair and maintenance times.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “processing circuit, ” “module” or “system.” Furthermore, aspects of the present invention may take the form of a computer program product embodied in one or more computer readable medium(s) having computer readable program code embodied thereon. The term “circuit” means either a single component or a multiplicity of components, either active and/or passive, that are coupled together to provide or perform a desired function. The term “signal” means at least one current, voltage, or data signal. The term “module” means a circuit (whether integrated or otherwise), a group of such circuits, a processor(s), a processor(s) implementing software, or a combination of a circuit (whether integrated or otherwise), a group of such circuits, a processor(s) and/or a processor(s) implementing software.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible storage medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a task or a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A computer implemented method of detecting events in an electrical network, the method comprising:
measuring a plurality of electrical parameters on said electrical network;
detecting a precursor event;
capturing said measured plurality of electrical parameters;
analyzing said plurality of electrical parameters;
automatically categorizing said precursor event; and,
transmitting a plurality of electronic notifications in response to said categorization of said precursor event.

2. The method of claim 1 further comprising the step of performing a plurality of analysis prior to categorizing said precursor event, wherein said categorization is determined by said analysis.

3. The method of claim 2 wherein said analysis are executed in parallel.

4. The method of claim 3 wherein said analysis are selected from a group comprising: reactance to fault, phase fault line-neutral voltage, phase fault line-line voltage, magnetizing inrush, subcycle fault, long RMS voltage variation, three-phase fault, overcurrent, arc voltage estimation, capacitor switching transients, steady state unbalance, and steady state power factor.

5. The method of claim 2 wherein said plurality of electronic notifications include electronic mail and webpage notifications.

6. The method of claim 5 wherein said plurality of electronic notifications further include at least one of a short message service (SMS), a pager message, a voicemail, and an really-simple-syndication (RSS) feed.

7. The method of claim 5 wherein said plurality of electronic notifications include an integration of data from a plurality of sources.

8. The method of claim 7 wherein said integration of data includes a location field, a time field, a event type and at least one electrical parameter measurement.

9. An apparatus for detecting events in an electrical network, said apparatus comprising:
a memory; and
one or more servers in communication with said memory, said one or more servers configured to perform a method comprising:
measuring a plurality of electrical parameters on said electrical network;
detecting a precursor event;
capturing said measured plurality of electrical parameters to said memory;
analyzing said plurality of electrical parameters;
automatically categorizing said precursor event with said one or more servers; and,
transmitting with said one or more servers a plurality of electronic notifications in response to said categorization of said precursor event.

10. The apparatus of claim 9 further comprising the step of performing a plurality of analysis prior to categorizing said precursor event, wherein said categorization is determined by said analysis.

11. The apparatus of claim 10 wherein said analysis are executed in parallel.

12. The apparatus of claim 11 wherein said analysis are selected from a group comprising: reactance to fault, phase fault line-neutral voltage, phase fault line-line voltage, magnetizing inrush, subcycle fault, long RMS voltage variation, three-phase fault, overcurrent, arc voltage estimation, capacitor switching transients, steady state unbalance, and steady state power factor.

13. The apparatus of claim 10 wherein said plurality of electronic notifications include electronic mail and webpage notifications.

14. The apparatus of claim 13 wherein said plurality of electronic notifications further include at least one of a short message service (SMS), a pager message, a voicemail, and an really-simple-syndication (RSS) feed.

15. The apparatus of claim 13 wherein said plurality of electronic notifications include an integration of data from a plurality of sources.

16. The apparatus of claim 15 wherein said integration of data includes a location field, a time field, a event type and at least one electrical parameter measurement.

17. A computer program product for executing a task of detecting events in an electrical network with a computer system, the computer program product comprising:
a tangible storage medium readable by a processing circuit and storing instructions for execution by the processing circuit for performing a method comprising:
measuring a plurality of electrical parameters on said electrical network;
detecting a precursor event;
capturing said measured plurality of electrical parameters;
analyzing said plurality of electrical parameters;
automatically categorizing said precursor event; and,
transmitting a plurality of electronic notifications in response to said categorization of said precursor event.

18. The computer program product of claim 17 further comprising the step of performing a plurality of analysis prior to categorizing said precursor event, wherein said categorization is determined by said analysis.

19. The computer program product of claim 18 wherein said analysis are executed in parallel.

20. The computer program product of claim 19 wherein said analysis are selected from a group comprising: reactance to fault, phase fault line-neutral voltage, phase fault line-line voltage, magnetizing inrush, subcycle fault, long RMS voltage variation, three-phase fault, overcurrent, arc voltage estimation, capacitor switching transients, steady state unbalance, and steady state power factor.

21. The computer program product of claim 18 wherein said plurality of electronic notifications include electronic mail and webpage notifications.

22. The computer program product of claim 21 wherein said plurality of electronic notifications further include at least one of a short message service (SMS), a pager message, a voicemail, and an really-simple-syndication (RSS) feed.

23. The computer program product of claim 21 wherein said plurality of electronic notifications include an integration of data from a plurality of sources.

24. The computer program product of claim 23 wherein said integration of data includes a location field, a time field, a event type and at least one electrical parameter measurement.
